(19) United States
(12) Patent Application Publication
(10) Pub. No.: US 2026/0173824 A1
(43) Pub. Date: Jun. 18, 2026

(54) VERTICALLY STACKED TEST STRUCTURE AND FABRICATION METHOD THEREFOR, AND SEMICONDUCTOR DEVICE HAVING VERTICALLY STACKED TEST STRUCTURE AND FABRICATION METHOD THEREFOR

(71) Applicant: SAMSUNG ELECTRONICS CO., LTD., Suwon-si (KR)

(72) Inventors: Hyunjae Cho, Suwon-si (KR); Daeho KANG, Suwon-si (KR); Soojung KIM, Suwon-si (KR); Jeonghyun KIM, Suwon-si (KR); Hyunjee JEON, Suwon-si (KR); Dongmin KIM, Suwon-si (KR); Yeongseong KIM, Suwon-si (KR); Insung KIM, Suwon-si (KR); Jaehyoung KIM, Suwon-si (KR); Kwangseok MAENG, Suwon-si (KR); Sanghyun LEE, Suwon-si (KR); Jinhee JANG, Suwon-si (KR); Noyoung CHUNG, Suwon-si (KR)

(73) Assignee: SAMSUNG ELECTRONICS CO., LTD., Suwon-si (KR)

(21) Appl. No.: 18/982,467

(22) Filed: Dec. 16, 2024

(30) Foreign Application Priority Data
Jan. 15, 2024 (KR) 10-2024-0006306
May 28, 2024 (KR) 10-2024-0069521

(51) Int. Cl. H01L 21/66

(52) U.S. Cl. CPC H10P 74/273; H10P 74/238

(57) ABSTRACT

A semiconductor device includes a semiconductor substrate; and a test structure on the semiconductor substrate. The test structure includes: a first test pattern; a second test pattern disposed above the first test pattern; and a dummy pattern located between the first test pattern and the second test pattern, and wherein the first test pattern, the dummy pattern, and the second test pattern at least partially overlap in a vertical direction.

### CROSS-REFERENCE TO RELATED APPLICATIONS

This application is based on and claims priority under 35 U.S.C. § 119 to Korean Patent Application Nos. 10-2024-0006306, filed on Jan. 15, 2024, and 10-2024-0069521, filed on May 28, 2024, in the Korean Intellectual Property Office, the disclosures of which are incorporated by reference herein in their entireties.

### BACKGROUND

### 1. Field

The disclosure relates to a vertically stacked test structure and a fabrication method of the vertically stacked test structure, and a semiconductor device including the vertically stacked test structure and a fabrication method of the vertically stacked test structure. More particularly, the disclosure relates to a vertically stacked test structure including a plurality of test patterns and a fabrication method of the vertically stacked test structure. The disclosure relates to a semiconductor device including the vertically stacked test structure and a fabrication method of the vertically stacked test structure.

### 2. Description of Related Art

Vertical alignment between a lower pattern and an upper pattern formed on a semiconductor substrate is referred to as “overlay.” In order to prevent defects caused by misalignment between the lower pattern and the upper pattern, the overlay between the lower pattern and the upper pattern is measured using an overlay measuring device.

### SUMMARY

Provided are a vertically stacked test structure having improved space efficiency and a fabricating method of the vertically stacked test structure. Provided is a semiconductor device including the vertically stacked test structure and a fabricating method of the vertically stacked test structure.

Also, the aspects of the disclosure are not limited to the aforementioned object, but other aspects not described herein will be understood by those skilled in the art from the following description.

According to an aspect of the disclosure, a semiconductor device includes: a semiconductor substrate; and a test structure on the semiconductor substrate. The test structure includes: a first test pattern; a second test pattern disposed above the first test pattern; and a dummy pattern located between the first test pattern and the second test pattern, and wherein the first test pattern, the dummy pattern, and the second test pattern at least partially overlap in a vertical direction.

According to an aspect of the disclosure, a method of fabricating a test structure, includes: forming a first test pattern on a semiconductor substrate; forming a dummy pattern on the first test pattern; and forming a second test pattern on the dummy pattern, wherein the first test pattern, the dummy pattern, and the second test pattern at least partially overlap in a vertical direction.

According to an aspect of the disclosure, a method of fabricating a semiconductor device, includes: preparing a semiconductor substrate; performing a first semiconductor process on the semiconductor substrate; forming a dummy pattern on the semiconductor substrate; performing a second semiconductor process on the semiconductor substrate; and performing a subsequent semiconductor process on the semiconductor substrate, wherein the performing of the first semiconductor process includes forming a first test pattern on the semiconductor substrate, wherein the performing of the second semiconductor process includes forming a second test pattern on the semiconductor substrate, and wherein the first test pattern, the dummy pattern, and the second test pattern at least partially overlap in a vertical direction.

### BRIEF DESCRIPTION OF THE DRAWINGS

Embodiments will be more clearly understood from the following detailed description taken in conjunction with the accompanying drawings in which:

FIG. 1 is a plan view showing a semiconductor substrate for forming a semiconductor device according to an embodiment;

FIG. 2 is a partially enlarged view of some semiconductor dies of FIG. 1;

FIG. 3 is a perspective view showing a test structure according to an embodiment;

FIG. 4 is a cross-sectional view showing a test structure according to an embodiment;

FIGS. 5 to 9 are perspective views showing a test structure according to an embodiment;

FIG. 10 is a perspective view showing a test structure according to an embodiment;

FIG. 11 is a cross-sectional view showing a test structure according to an embodiment;

FIGS. 12 to 14 are plan views showing a dummy pattern according to an embodiment;

FIG. 15 illustrates a process system for fabricating a semiconductor device according to an embodiment;

FIG. 16 illustrates a first overlay measuring device, a second overlay measuring device, and a control device, according to an embodiment;

FIG. 17 is a perspective view showing a test structure according to an embodiment;

FIG. 18 is a partially enlarged view of some semiconductor dies of FIG. 1;

FIG. 19 illustrates a method of fabricating a test structure, according to an embodiment;

FIG. 20 illustrates a method of forming a dummy pattern, according to an embodiment;

FIG. 21 illustrates a method of designing a dummy pattern, according to an embodiment; and

FIG. 22 illustrates a method of fabricating a semiconductor device, according to an embodiment.

### DETAILED DESCRIPTION

The description merely illustrates the principles of the disclosure. Those skilled in the art will be able to devise one or more arrangements that, although not explicitly described herein, embody the principles of the disclosure. Furthermore, all examples recited herein are principally intended expressly to be only for explanatory purposes to help the reader in understanding the principles of the disclosure and the concepts contributed by the inventor to furthering the art and are to be construed as being without limitation to such specifically recited examples and conditions. Moreover, all statements herein reciting principles, aspects, and embodiments of the disclosure, as well as specific examples thereof, are intended to encompass equivalents thereof.

Terms used in the disclosure are used only to describe a specific embodiment, and may not be intended to limit the scope of another embodiment. A singular expression may include a plural expression unless it is clearly meant differently in the context. The terms used herein, including a technical or scientific term, may have the same meaning as generally understood by a person having ordinary knowledge in the technical field described in the present disclosure. Terms defined in a general dictionary among the terms used in the present disclosure may be interpreted with the same or similar meaning as a contextual meaning of related technology, and unless clearly defined in the present disclosure, it is not interpreted in an ideal or excessively formal meaning. In some cases, even terms defined in the disclosure cannot be interpreted to exclude embodiments of the present disclosure.

In one or more embodiments of the disclosure described below, a hardware approach is described as an example. However, since the one or more embodiments of the disclosure include technology that uses both hardware and software, the various embodiments of the present disclosure do not exclude a software-based approach.

In addition, in the disclosure, in order to determine whether a specific condition is satisfied or fulfilled, an expression of more than or less than may be used, but this is only a description for expressing an example, and does not exclude description of more than or equal to or less than or equal to. A condition described as ‘more than or equal to’ may be replaced with ‘more than’, a condition described as ‘less than or equal to’ may be replaced with ‘less than’, and a condition described as ‘more than or equal to and less than’ may be replaced with ‘more than and less than or equal to’.

The terms “include” and “comprise”, and the derivatives thereof refer to inclusion without limitation. The term “or” is an inclusive term meaning “and/or”. The phrase “associated with,” as well as derivatives thereof, refer to include, be included within, interconnect with, contain, be contained within, connect to or with, couple to or with, be communicable with, cooperate with, interleave, juxtapose, be proximate to, be bound to or with, have, have a property of, have a relationship to or with, or the like. The term “controller” refers to any device, system, or part thereof that controls at least one operation. The functionality associated with any particular controller may be centralized or distributed, whether locally or remotely. The phrase “at least one of,” when used with a list of items, means that different combinations of one or more of the listed items may be used, and only one item in the list may be needed. For example, “at least one of A, B, and C” includes any of the following combinations: A, B, C, A and B, A and C, B and C, and A and B and C, and any variations thereof. As an additional example, the expression “at least one of a, b, or c” may indicate only a, only b, only c, both a and b, both a and c, both b and c, all of a, b, and c, or variations thereof. Similarly, the term “set” means one or more. Accordingly, the set of items may be a single item or a collection of two or more items.

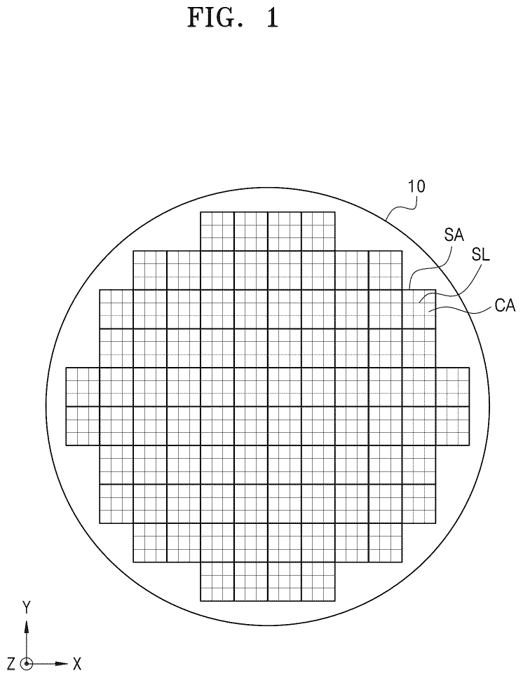

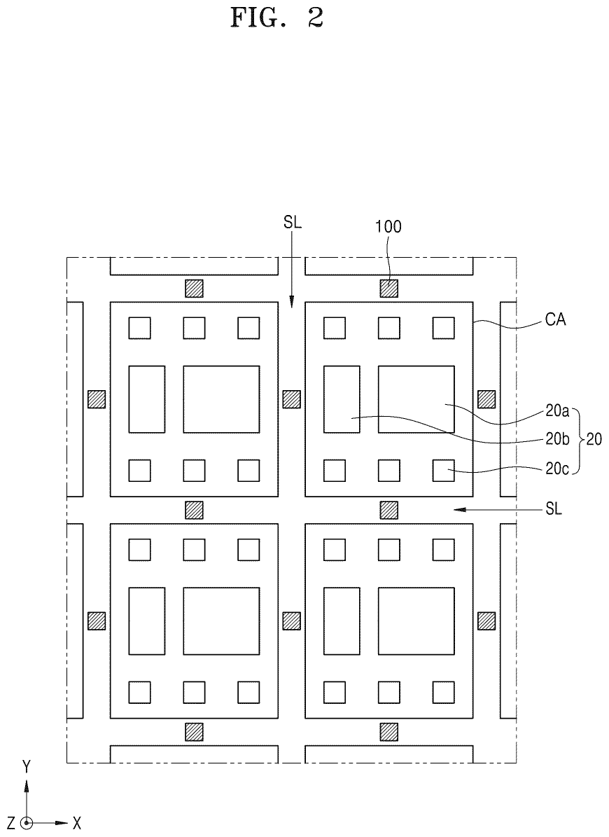

FIG. 1 is a plan view showing a semiconductor substrate 10 for forming a semiconductor device according to an embodiment. FIG. 2 is a partially enlarged view of some semiconductor dies of FIG. 1.

Referring to FIGS. 1 and 2, the semiconductor substrate 10 may have a plurality of shot regions SA. Each of the shot regions SA may represent a region exposed by one exposure process. One shot region SA may include one chip region CA or a plurality of chip regions CA. A scribe lane region SL may be located between the chip regions CA. The chip regions CA may be defined by the scribe lane region SL.

Each of the chip regions CA may include a plurality of circuit regions 20. Each of the plurality of circuit regions 20 may include a logic circuit region 20a, a memory region 20b, an input/output element region 20c, etc. Herein, the chip region CA may be referred to as an ‘in-cell region.’

In some embodiments, a plurality of test structures 100 may be substantially evenly arranged on the semiconductor substrate 10. In some embodiments, the plurality of test structures 100 may be evenly arranged on the scribe lane region SL. In some embodiments, the plurality of test structures 100 may be evenly arranged on the chip region CA (the in-cell region). In some embodiments, the plurality of test structures 100 may be evenly arranged on the semiconductor substrate 10 regardless of the scribe lane region SL and the chip region CA.

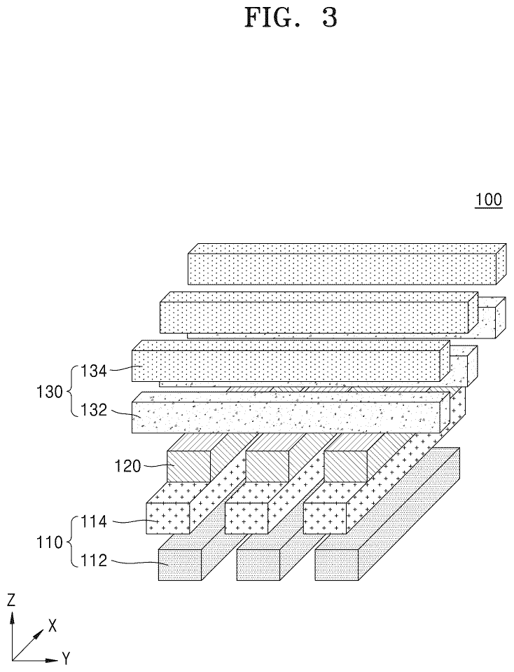

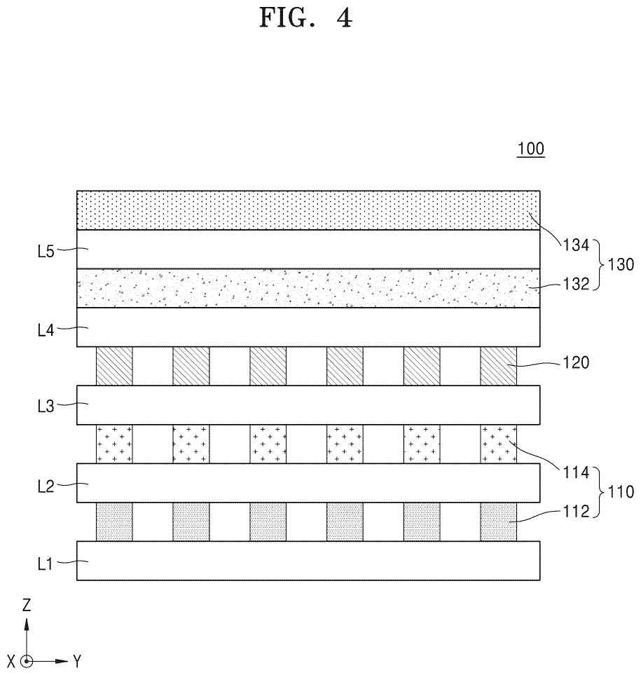

FIG. 3 is a perspective view showing a test structure 100 according to an embodiment. FIG. 4 is a cross-sectional view showing the test structure 100 according to an embodiment. A description is given below with reference to FIGS. 1 and 2.

Referring to FIGS. 3 and 4, the test structure 100 may include a first test pattern 110, a dummy pattern 120, and a second test pattern 130. The first test pattern 110 may include a first lower mark 112 and a first upper mark 114. The second test pattern 130 may include a second lower mark 132 and a second upper mark 134.

The first lower mark 112 may be formed on a first layer L1. The first upper mark 114 may be formed on a second layer L2. The dummy pattern 120 may be formed on a third layer L3. The second lower mark 132 may be formed on a fourth layer L4. The second upper mark 134 may be formed on a fifth layer L5.

The first lower mark 112 and the first upper mark 114 of the first test pattern 110 may form a pair. Also, the second lower mark 132 and the second upper mark 134 of the second test pattern 130 may form a pair.

The first lower mark 112 and the second lower mark 132 may represent a main pattern (MP). The first upper mark 114 and the second upper mark 134 may represent a vernier pattern (VP).

FIGS. 3 and 4 illustrate an embodiment in which the first test pattern 110, the dummy pattern 120, and the second test pattern 130 include a diffraction-based overlay (DBO) mark, but the disclosure is not limited thereto. For example, the first test pattern 110, the dummy pattern 120, and/or the second test pattern 130 may include other types of overlay marks, such as an image-based overlay (IBO) mark, a box-in-box (BIB) overlay mark, and/or an advanced image metrology (AIM) overlay mark.

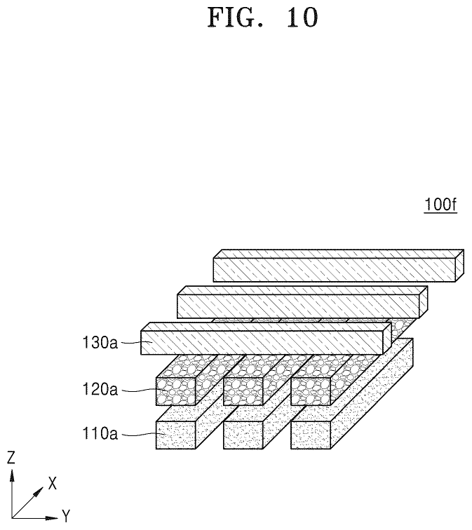

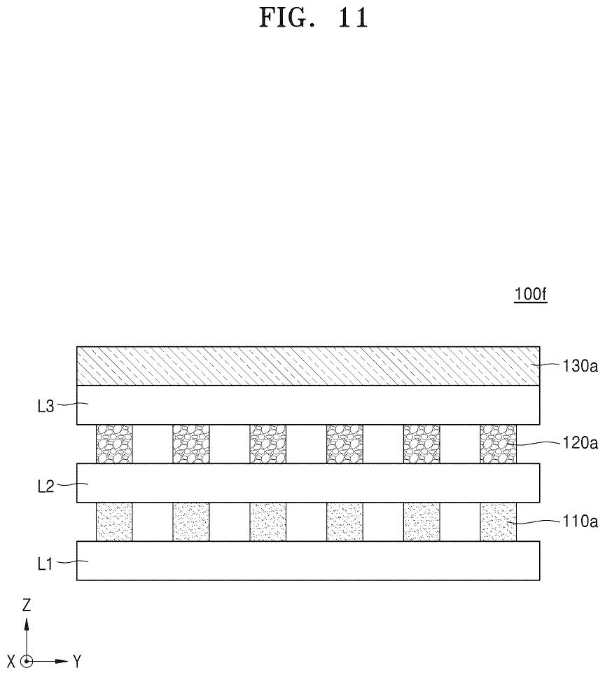

In some embodiments, the first test pattern 110, the dummy pattern 120, and/or the second test pattern 130 may include an alignment mark. The embodiment in which the first test pattern 110, the dummy pattern 120 and/or the second test pattern 130 include alignment marks is described in detail below with reference to FIGS. 10 and 11.

The dummy pattern 120 may be selected in various ways based on the characteristics of the first test pattern 110 and/or the second test pattern 130. In an embodiment, the dummy pattern 120 may include an opaque layer.

In an embodiment, the first test pattern 110 and the second test pattern 130 may include the same type of overlay mark. In some embodiments, the first test pattern 110 and the second test pattern 130 may include different types of overlay marks. In an embodiment, the first test pattern 110 and the dummy pattern 120 may include the same type of overlay mark. In some embodiments, the first test pattern 110 and the dummy pattern 120 may include different types of overlay marks. In an embodiment, the dummy pattern 120 and the second test pattern 130 may include the same type of overlay mark. In some embodiments, the dummy pattern 120 and the second test pattern 130 may include different types of overlay marks.

The first test pattern 110, the dummy pattern 120, and the second test pattern 130 may be sequentially stacked in a vertical direction (a Z direction). The dummy pattern 120 may be located between the first test pattern 110 and the second test pattern 130. In addition, the first test pattern 110, the dummy pattern 120, and the second test pattern 130 may at least partially overlap each other in the vertical direction (the Z direction).

As illustrated in FIG. 3, a direction parallel to a main surface of the semiconductor substrate 10 may be defined as a horizontal direction (an X direction and/or a Y direction), and a direction perpendicular to the horizontal direction (the X direction and/or the Y direction) may be defined as a vertical direction (a Z direction).

The first test pattern 110, the dummy pattern 120, and/or the second test pattern 130 may include a plurality of patterns having a grating shape, a plurality of patterns having a bar shape, and/or a plurality of patterns having a slit shape. For example, the first test pattern 110, the dummy pattern 120, and/or the second test pattern 130 may include a line-and-space pattern.

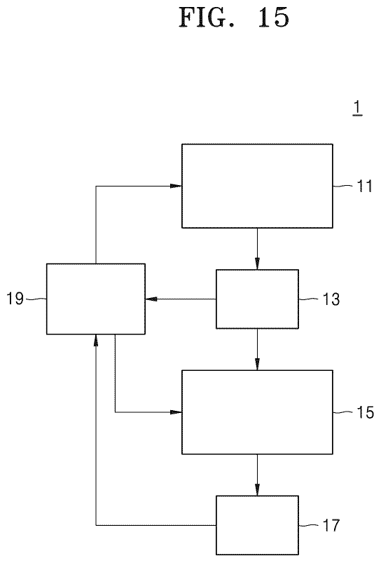

When measuring a test pattern at a higher vertical level than the dummy pattern 120, the dummy pattern 120 may reduce a signal (i.e., noise) from the dummy pattern 120 and/or a test pattern at a lower vertical level than the dummy pattern 120. For example, when a second overlay measuring device 17 (FIG. 15) measures the second test pattern 130, the dummy pattern 120 may reduce noise caused by a test pattern at a lower vertical level than the second test pattern 130. Therefore, when a dummy pattern 120 is located between a plurality of test patterns, the plurality of test patterns may be stacked in the vertical direction (the Z direction).

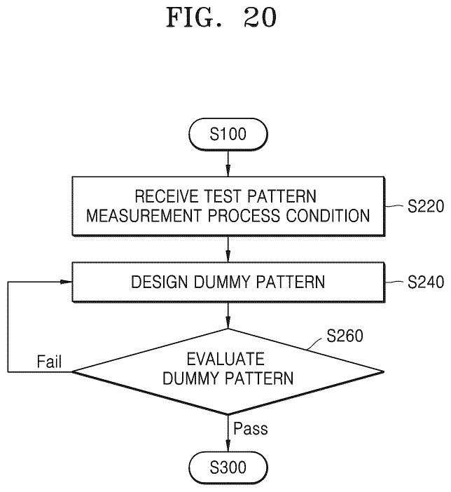

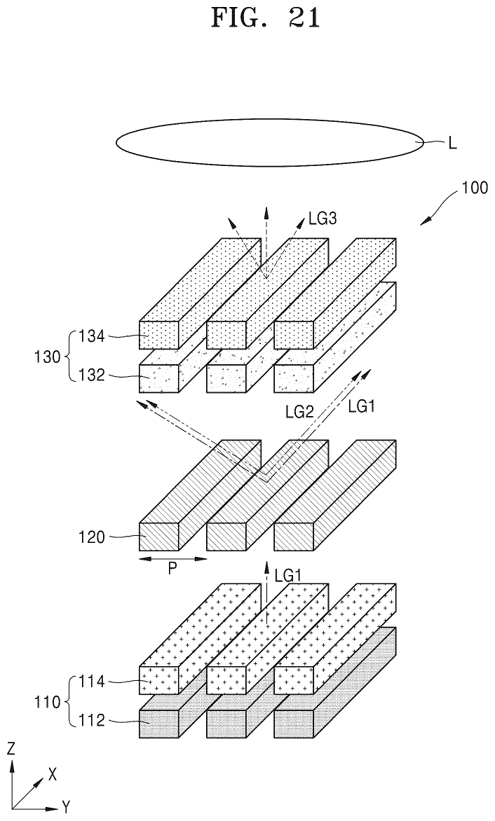

When measuring the test pattern at the higher vertical level than the dummy pattern 120, the dummy pattern 120 reduces noise from the dummy pattern 120 and/or the test pattern at the lower vertical level than the dummy pattern 120, which is described in detail below with reference to FIGS. 20 and 21.

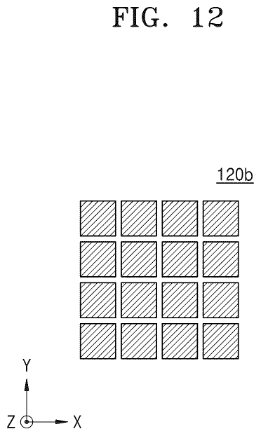

In some embodiments, the planar shape of the dummy pattern 120 may have any polygonal, circular, and/or elliptical shape. Also, the dummy pattern 120 may be arranged in various manners. The other shapes and arrangements of the dummy pattern 120 are described in detail below with reference to FIGS. 12 to 14.

FIGS. 3 and 4 illustrate that the first test pattern 110 includes a plurality of patterns having a bar shape extending in the first horizontal direction (the X direction) and the second test pattern 130 includes a plurality of patterns having a bar shape extending in the second horizontal direction (the Y direction). However, the disclosure is not limited thereto.

Also, a direction in which the first test pattern 110 extends (hereinafter, referred to as an extension direction of the first test pattern 110) may be substantially same or the same as the extension direction of the dummy pattern 120, and the extension direction of the first test pattern 110 may be different from the extension direction of the second test pattern 130. For example, the extension direction of the first test pattern 110 may be (substantially) perpendicular to the extension direction of the second test pattern 130. In an embodiment, the second test pattern 130 may have a shape obtained by rotating the first test pattern 110 at an angle of 90° on a plane.

In some embodiments, the extension direction of the first test pattern 110 may be different from the extension direction of the dummy pattern 120. In some embodiments, the extension direction of the first test pattern 110 may be substantantially same or the same as the extension direction of the second test pattern 130.

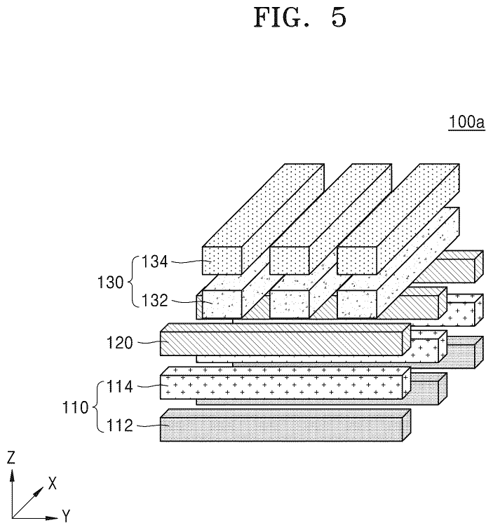

The extension direction of the first test pattern 110, the extension direction of the dummy pattern 120, and the extension direction of the second test pattern 130 may be formed in various manners. The combinations of various extension directions of each of the first test pattern 110, the dummy pattern 120, and the second test pattern 130 are described in detail with reference to FIGS. 5 to 9.

In an embodiment, the dummy pattern 120 may extend in the same or substantially same direction as a test pattern that is adjacent to the dummy pattern 120 at a lower vertical level than the dummy pattern 120. In some embodiments, the dummy pattern 120 may extend in a different direction from the test pattern that is adjacent to the dummy pattern 120 at the lower vertical level than the dummy pattern 120. For example, the dummy pattern 120 may extend in a direction (substantially) perpendicular to the extension direction of the test pattern that is adjacent to the dummy pattern 120 at the lower vertical level than the dummy pattern 120.

In an embodiment, the dummy pattern 120 may extend in the same or substantially same direction as the extension direction of the test pattern that is adjacent to the dummy pattern 120 at a higher vertical level than the dummy pattern 120. In some embodiments, the dummy pattern 120 may extend in a different direction from the test pattern that is adjacent to the dummy pattern 120 at the higher vertical level than the dummy pattern 120. For example, the dummy pattern 120 may extend in a direction perpendicular to the extension direction of the test pattern that is adjacent to the dummy pattern 120 at the higher vertical level than the dummy pattern 120.

According to the disclosure, the test structure 100 may include a plurality of test patterns overlapping each other in the vertical direction (the Z direction). Accordingly, the test patterns may be effectively arranged in the semiconductor substrate 10, and thus, the space margin of the semiconductor substrate 10 may increase.

In addition, the test structure 100 according to the disclosure includes the dummy pattern 120, and thus, the influence of the first test pattern 110 on the measurement may be reduced when measuring the second test pattern 130. Therefore, the test structure 100 according to the disclosure may be measured with high reliability.

FIGS. 5 to 9 are perspective views showing a test structure according to an embodiment. A description is given below with reference to FIGS. 3 and 4.

A first test pattern 110, a dummy pattern 120, and a second test pattern 130 of FIGS. 5 to 9 may be substantially same or the same as the first test pattern 110, the dummy pattern 120, and the second test pattern 130 of FIGS. 3 and 4, respectively.

Referring to FIG. 5, the first test pattern 110 of a test structure 100a may extend in the same direction as the dummy pattern 120, and the first test pattern 110 may extend in a different direction from the second test pattern 130. In an embodiment, the extension direction of the first test pattern 110 may be (substantially) perpendicular to the extension direction of the second test pattern 130. In an embodiment, the second test pattern 130 may have a shape obtained by rotating the first test pattern 110 at an angle of 90° on a plane.

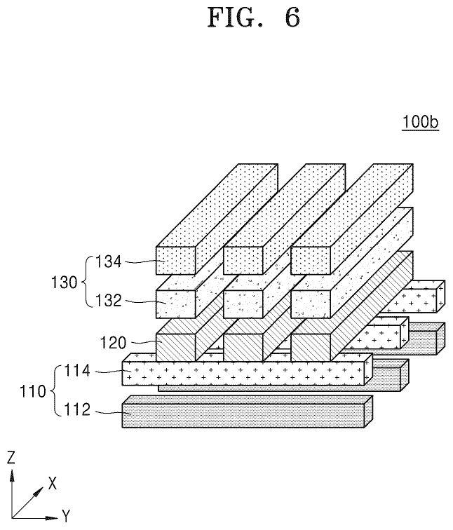

Referring to FIG. 6, the first test pattern 110 of a test structure 100b may extend in a different direction from the dummy pattern 120, and the first test pattern 110 may extend in a different direction from the second test pattern 130. Also, the dummy pattern 120 may extend in the same direction as the second test pattern 130. In an embodiment, the extension direction of the first test pattern 110 may be (substantially) perpendicular to the extension direction of the second test pattern 130. In an embodiment, the second test pattern 130 may have a shape obtained by rotating the first test pattern 110 at an angle of 90° on a plane.

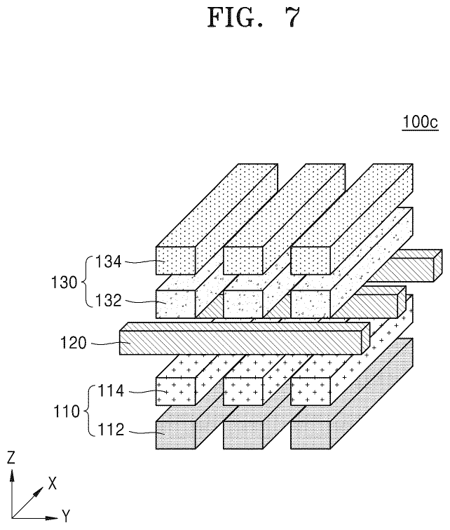

Referring to FIG. 7, the first test pattern 110 of a test structure 100c may extend in a different direction from the dummy pattern 120, and the first test pattern 110 may extend in the same direction as the second test pattern 130. In an embodiment, the extension direction of the first test pattern 110 may be (substantially) perpendicular to the extension direction of the dummy pattern 120. In an embodiment, the dummy pattern 120 may have a shape obtained by rotating the first test pattern 110 at an angle of 90° on a plane.

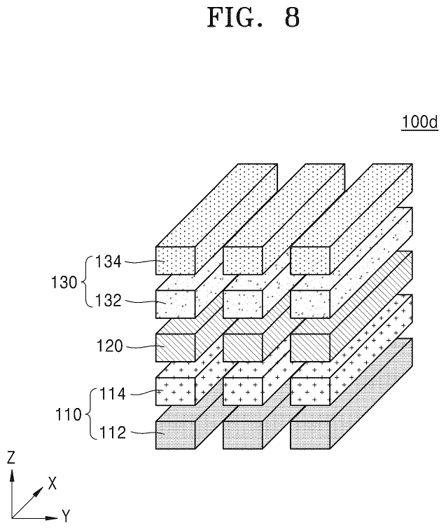

Referring to FIG. 8, the first test pattern 110, the dummy pattern 120, and the second test pattern 130 of a test structure 100d may all extend in the same direction.

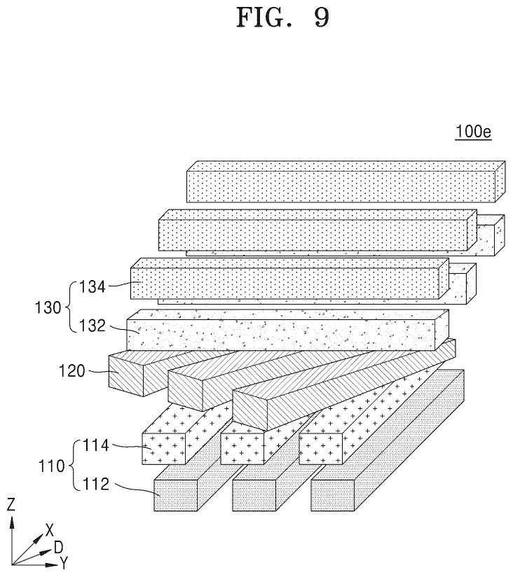

Referring to FIG. 9, the dummy pattern 120 of a test structure 100e may extend in a direction different from the extension direction of each of the first test pattern 110 and the second test pattern 130. That is, the extension direction of the dummy pattern 120 may be different from the extension direction of the first test pattern 110, and the extension direction of the dummy pattern 120 may also be different from the extension direction of the second test pattern 130. For example, the dummy pattern 120 may extend in a third horizontal direction D (a diagonal direction).

However, the disclosure is not limited thereto. Each of the first test pattern 110, the dummy pattern 120, and the second test pattern 130 may be arranged in various combinations.

FIG. 10 is a perspective view showing a test structure 100f according to an embodiment. FIG. 11 is a cross-sectional view showing the test structure 100f according to an embodiment. A description is given below with reference to FIGS. 3 and 4.

Referring to FIGS. 10 and 11, the test structure 100f may include a first test pattern 110a, a dummy pattern 120a, and a second test pattern 130a. Each of the first test pattern 110a and the second test pattern 130a may include marks arranged in a single layer.

The first test pattern 110a may be formed on a first layer L1, the dummy pattern 120a may be formed on a second layer L2, and the second test pattern 130a may be formed on a third layer L3.

As described above, the first test pattern 110a, the dummy pattern 120a, and/or the second test pattern 130a may include an alignment mark. The alignment marks may include a pattern arranged in a single layer on one layer.

FIGS. 12 to 14 are plan views showing a dummy pattern according to an embodiment. A description is given below with reference to FIGS. 3 and 4.

Referring to FIG. 12, the planar shape of a dummy pattern 120b may be square. The dummy pattern 120b may be arranged in a checkerboard pattern in a plan view.

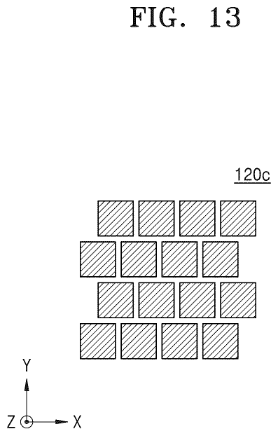

Referring to FIG. 13, the planar shape of the dummy pattern 120b may be square. The dummy pattern 120c may be arranged in a staggered shape in a plan view.

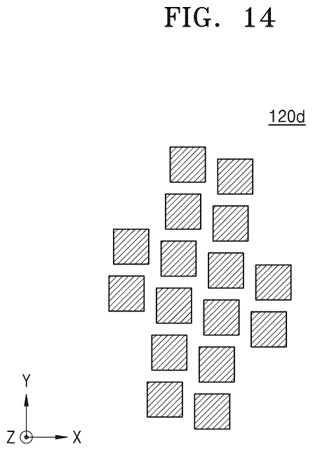

Referring to FIG. 14, the planar shape of a dummy pattern 120d may be square. The dummy pattern 120d may be arranged in a pinwheel shape in a plan view. The dummy pattern 120d may be arranged in a radial shape with respect to a center point. Accordingly, the dummy pattern 120d may be arranged equidistantly based on the center point.

As described in detail below with reference to FIGS. 20 and 21, the dummy patterns 120, 120a, 120b, 120c, and 120d may reduce signals generated from the dummy patterns 120, 120a, 120b, 120c, and 120d and test patterns at a lower vertical level than the dummy patterns 120, 120a, 120b, 120c, and 120d. The shapes and arrangements of the dummy patterns 120, 120a, 120b, 120c, and 120d may be determined according to the test conditions (e.g., overlay measurement conditions) and the shapes of test patterns adjacent to the dummy patterns 120, 120a, 120b, 120c, and 120d.

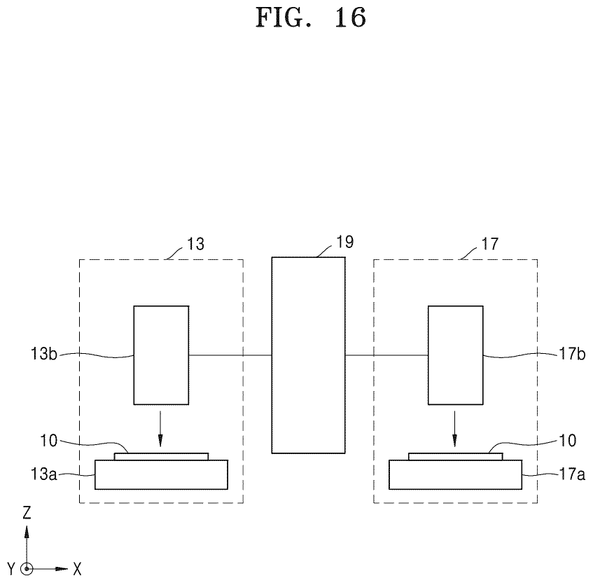

FIG. 15 illustrates a process system for fabricating a semiconductor device according to an embodiment. FIG. 16 illustrates a first overlay measuring device, a second overlay measuring device, and a control device, according to an embodiment. A description is given below with reference to FIGS. 3 and 4.

Referring to FIGS. 15 and 16, a semiconductor process system 1 may include first semiconductor process equipment 11, a first measuring device 13 (that is configured to perform a first measurement of a first test pattern 110 formed using the first semiconductor process equipment 11), a second semiconductor process equipment 15 (that is configured to perform a second semiconductor process), and a second measuring device 17 (that is configured to perform a second measurement of a second test pattern 130 formed using the second semiconductor process equipment 15). In addition, the semiconductor process system 1 may further include a control device 19 configured to transmit and receive signals from the first measuring device 13 and the second measuring device 17.

As shown in FIG. 16, the first measuring device 13 may include a first tray part 13a, on which a semiconductor substrate 10 is placed, and a first measuring part 13b for measuring the first test pattern 110. In an embodiment, the first measuring part 13b may measure the overlay of the first test pattern 110 using light, and the control device 19 may generate overlay error data using data that is measured and obtained by the first measuring part 13b. The overlay error data generated as described above may be fed back to the first semiconductor process equipment 11.

The second measuring device 17 may include a second tray part 17a, on which the semiconductor substrate 10 is placed, and a second measuring part 17b for measuring the second test pattern 130. In an embodiment, the second measuring part 17b may measure the overlay of the second test pattern 130 using light, and the control device 19 may generate overlay error data using data that is measured and obtained by the second measuring part 17b. The overlay error data generated as described above may be fed back to the second semiconductor process equipment 15.

In some embodiments, the first measuring device 13 may measure the position of the first test pattern 110 using light. Also, the second measuring device 17 may measure the position of the second test pattern 130 using light. On the basis of the positions of the first test pattern 110 and the second test pattern 130, the semiconductor process system 1 may measure the alignment of a plurality of test patterns.

In an embodiment, the first measuring device 13 may be identical to the second measuring device 17. In some embodiments, the first measuring device 13 may be different from the second measuring device 17.

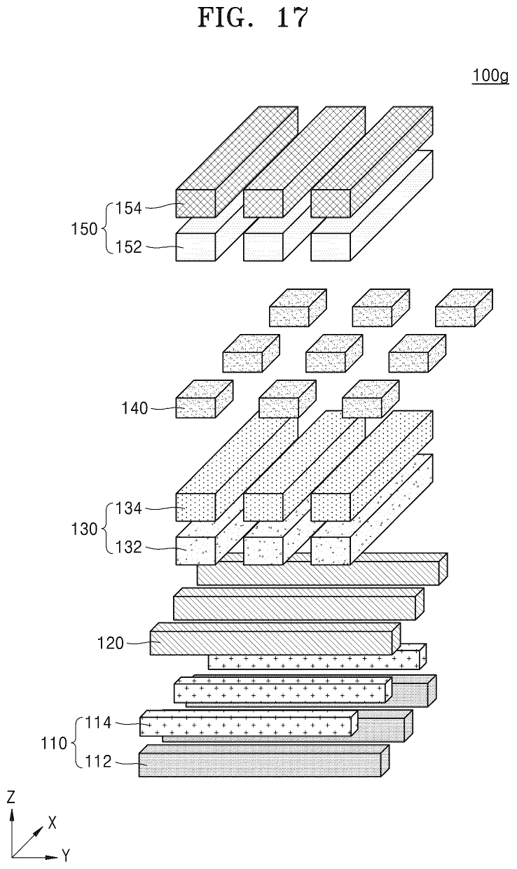

FIG. 17 is a perspective view showing a test structure 100g according to an embodiment. A description is given below with reference to FIGS. 3 and 4.

Referring to FIG. 17, the test structure 100g may include a first test pattern 110, a dummy pattern 120, a second test pattern 130, an upper dummy pattern 140, and a third test pattern 150. For convenience of description, hereinafter, the dummy pattern 120 may be referred to as a first dummy pattern 120, and the upper dummy pattern 140 may be referred to as a second dummy pattern 140.

The first test pattern 110 may include a first lower mark 112 and a first upper mark 114. The second test pattern 130 may include a second lower mark 132 and a second upper mark 134. The third test pattern 150 may include a third lower mark 152 and a third upper mark 154.

The first lower mark 112 and the first upper mark 114 of the first test pattern 110 may form a pair. Also, the second lower mark 132 and the second upper mark 134 of the second test pattern 130 may form a pair. Also, the third lower mark 152 and the third upper mark 154 of the third test pattern 150 may form a pair.

The first lower mark 112, the second lower mark 132, and the third lower mark 152 may include main patterns. The first upper mark 114, the second upper mark 134, and the third upper mark 154 may include vernier patterns.

The first test pattern 110, the first dummy pattern 120, the second test pattern 130, the second dummy pattern 140, and the third test pattern 150 may be sequentially stacked in the vertical direction (the Z direction). The first dummy pattern 120 may be located between the first test pattern 110 and the second test pattern 130. The second dummy pattern 140 may be located between the second test pattern 130 and the third test pattern 150. In addition, the first test pattern 110, the first dummy pattern 120, and the second test pattern 130 may at least partially overlap each other in the vertical direction (the Z direction). The second test pattern 130, the second dummy pattern 140, and the third test pattern 150 may at least partially overlap each other in the vertical direction (the Z direction).

The first dummy pattern 120 may reduce noise occurring in the first test pattern 110 and/or the first dummy pattern 120 when measuring the second test pattern 130 and/or the third test pattern 150. Also, the second dummy pattern 140 may reduce noise occurring in the first test pattern 110, the second test pattern 130, and/or the second dummy pattern 140 when measuring the third test pattern 150.

The first test pattern 110, the first dummy pattern 120, the second test pattern 130, the second dummy pattern 140, and/or the third test pattern 150 may include a plurality of patterns having a grating shape, a plurality of patterns having a bar shape, and/or a plurality of patterns having a slit shape. For example, the first test pattern 110, the first dummy pattern 120, the second test pattern 130, and/or the third test pattern 150 may include a line-and-space pattern. Also, for example, the second dummy pattern 140 may be square. However, the shape of each of the first test pattern 110, the first dummy pattern 120, the second test pattern 130, the second dummy pattern 140, and/or the third test pattern 150 may be modified in various manners.

Also, the extension direction of the first test pattern 110 may be substantially same as or the same as the extension direction of the first dummy pattern 120, and the extension direction of the first test pattern 110 may be different from the extension direction of the second test pattern 130. In an embodiment, the extension direction of the first test pattern 110 may be (substantially) perpendicular to the extension direction of the second test pattern 130. In some embodiments, the extension direction of the first test pattern 110 may be substantially the same as the extension direction of the second test pattern 130.

In an embodiment, the extension direction of the second test pattern 130 may be substantially same as or the same as the extension direction of the third test pattern 150. In some embodiments, the extension direction of the second test pattern 130 may be different from the extension direction of the third test pattern 150.

FIG. 17 illustrates that the test structure 100g includes three test patterns and two dummy patterns, but the disclosure is not limited thereto. For example, the test structure 100g may include four or more test patterns and/or three or more dummy patterns.

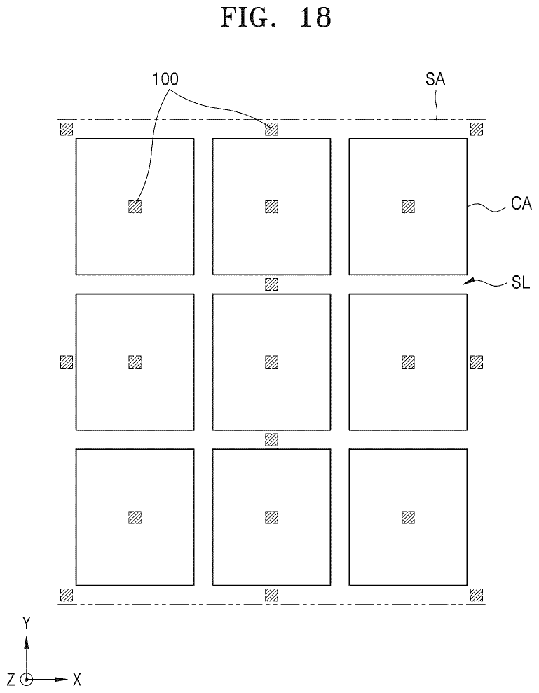

FIG. 18 is a partially enlarged view of some semiconductor dies of FIG. 1. A description is given below with reference to FIGS. 1 to 17.

Referring to FIG. 18, a plurality of test structures 100 may be provided on a semiconductor substrate 10 and evenly arranged within one shot region SA.

In some embodiments, a plurality of chip regions CA may be arranged in one shot region SA. The test structures 100 may be arranged at the same locations within each of the plurality of chip regions CA. For example, the locations of the test structures 100 arranged in one of the plurality of chip regions CA may be substantially same as or the same as the locations of the test structures 100 arranged in another one of the plurality of chip regions CA.

The test structures 100a, 100b, 100c, 100d, 100e, 100f, and 100g as illustrated in FIGS. 5 to 9, FIG. 10, FIG. 11, and FIG. 17 may be arranged on the semiconductor substrate 10.

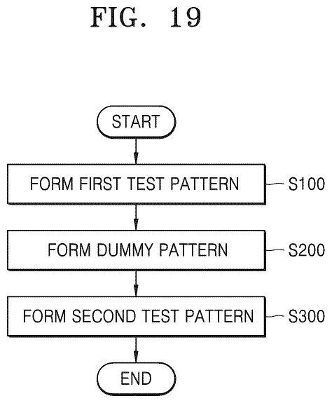

FIG. 19 illustrates a method of fabricating a test structure, according to an embodiment. A description is given below with reference to FIGS. 1 to 18.

Referring to FIG. 19, first, a first test pattern 110 may be formed on a semiconductor substrate 10 (S100). The first test pattern 110 may include a first lower mark 112 and a first upper mark 114. In an embodiment, the first test pattern 110 may have a line-and-space shape. In some embodiments, the first test pattern 110 may include a mark formed in a single layer.

Subsequently, a dummy pattern 120 may be formed on the first test pattern 110 (S200). The dummy pattern 120 may overlap the first test pattern 110 in the vertical direction (the Z direction). In an embodiment, the dummy pattern 120 may have a line-and-space shape. In an embodiment, the dummy pattern 120 may extend in the same direction as the direction in which the first test pattern 110 extends. In some embodiments, the dummy pattern 120 may extend in a different direction from the direction in which the first test pattern 110 extends. In some embodiments, the dummy pattern 120 may have a planar shape of square, circle, ellipse, and/or any polygon.

When measuring a test pattern at a higher vertical level than the dummy pattern 120, the dummy pattern 120 may reduce noise generated from the dummy pattern 120 and/or a test pattern at a lower vertical level than the dummy pattern 120.

A method of forming the dummy pattern 120 is described with reference to FIGS. 20 and 21.

FIG. 20 illustrates a method of forming a dummy pattern, according to an embodiment.

Referring to FIG. 20, a method of forming a dummy pattern 120 may first receive test pattern measurement process conditions (S220). Herein, the process conditions may include a process condition for measuring a test pattern at a higher vertical level than the dummy pattern 120. For example, the process conditions may include a process condition for measuring the second test pattern 130. For example, test pattern measuring processes may include an overlay measuring process and/or an alignment mark measuring process.

In an embodiment, the process conditions may include the wavelength and numerical aperture (NA) of light of an overlay measuring device. However, the process conditions are not limited to the above examples and may include various parameters of the overlay measuring device.

Subsequently, the dummy pattern 120 may be designed based on the process conditions (S240). The designing of the dummy pattern 120 may include selecting the shape and arrangement of the dummy pattern 120. Herein, the selecting of the arrangement of the dummy pattern 120 may include selecting the pitch of the dummy pattern 120.

The shape and arrangement of the dummy pattern 120 may be selected to minimize noise generated from the first test pattern 110 and/or the dummy pattern 120 when subsequently measuring a test pattern at a higher vertical level than the dummy pattern 120. For example, the shape and arrangement of the dummy pattern 120 may be selected to minimize noise generated from the first test pattern 110 and/or the dummy pattern 120 when subsequently measuring the second test pattern 130.

The shape of the dummy pattern 120 may be selected based on a test pattern adjacent to the dummy pattern 120. In an embodiment, the shape of the dummy pattern 120 may be selected based on a test pattern that is adjacent to the dummy pattern 120 at a higher vertical level than the dummy pattern 120. For example, the shape of the dummy pattern 120 may be selected based on the type of process of forming a test pattern at a higher vertical level than the dummy pattern 120 and/or the extension direction of the test pattern.

In some embodiments, the shape of the dummy pattern 120 may be selected based on a test pattern that is adjacent to the dummy pattern 120 at a lower vertical level than the dummy pattern 120. For example, the shape of the dummy pattern 120 may be selected based on the type of process of forming a test pattern at a lower vertical level than the dummy pattern 120 and/or the extension direction of the test pattern.

The method of selecting the arrangement of the dummy pattern 120 is described with reference to FIG. 21. FIG. 21 illustrates a method of designing a dummy pattern, according to an embodiment.

Referring to FIG. 21, a test structure 100 and a lens L are illustrated. Also, FIG. 21 illustrates first light LG1 reflected from a first test pattern 110, second light LG2 reflected from a dummy pattern 120, and third light (LG3) reflected from a second test pattern 130.

The dummy pattern 120 may be arranged so as to partially block the first light LG1 and partially transmit the first light LG1 to the outside of the numerical aperture (NA) of the lens L. For example, the dummy pattern 120 may be arranged such that first-order diffraction components of the first light LG1 are transmitted outside the NA of the lens L. Also, the dummy pattern 120 may be arranged such that the second light LG2 reflected from the dummy pattern 120 is also transmitted outside the NA of the lens L. The zeroth-order diffraction components and the first-order diffraction components of the third light (LG3) reflected from the second test pattern 130 may be incident onto the lens L.

The propagation path of the first-order diffraction components of the first light LG1 and/or the second light LG2 diffracted from the dummy pattern 120 may be controlled by regulating the shape and arrangement of the dummy pattern 120.

The arrangement of the dummy pattern 120 may be selected based on Bragg's law. Bragg's law may be expressed mathematically as follows.

$$n λ \sim pitch \times NA \qquad [ Equation ]$$

Here, n represents the diffraction order, λ represents the wavelength of light, pitch represents a pitch P of the dummy pattern 120, and NA represents the numerical aperture.

Therefore, in operation S220, the measurement process conditions (for example, wavelength of the overlay measuring device and NA of the overlay measuring device) of a test pattern measuring device are received, and thus, the pitch P of the dummy pattern 120 may be calculated using the above Equation. Also, in an embodiment, the shape and arrangement of the dummy pattern 120 may be selected so as to reduce measurement signal noise and increase the space efficiency of the test structure 100 which is to be fabricated.

Subsequently, the dummy pattern 120 may be evaluated (S260). The dummy pattern forming method may proceed to operation S300 if the dummy pattern 120 is excellent (pass) but may proceed to operation S240 if the dummy pattern 120 is poor (fail). The dummy pattern 120 may be evaluated by performing a simulation. For example, the simulation may include a rigorous coupled-wave analysis (RCWA) method or a finite-difference time-domain (FDTD) method. The simulation may determine whether patterning is possible when designing the dummy pattern 120 and whether the dummy pattern 120 functions as intended.

Referring back to FIG. 19, after forming the dummy pattern 120 (S200), the second test pattern 130 may be formed (S300). The second test pattern 130 may be formed on the dummy pattern 120. The second test pattern 130 may overlap the first test pattern 110 and/or the dummy pattern 120 in the vertical direction (the Z direction). The second test pattern 130 may include a second lower mark 132 and a second upper mark 134. In some embodiments, the second test pattern 130 may include a mark formed in a single layer.

In an embodiment, the second test pattern 130 may extend in a direction different from the extension direction of each of the first test pattern 110 and/or the dummy pattern 120. In an embodiment, the second test pattern 130 may extend in a direction perpendicular to the extension direction of each of the first test pattern 110 and/or the dummy pattern 120. In some embodiments, the second test pattern 130 may extend in the same direction as at least one of the extension directions of the first test pattern 110 and the dummy pattern 120.

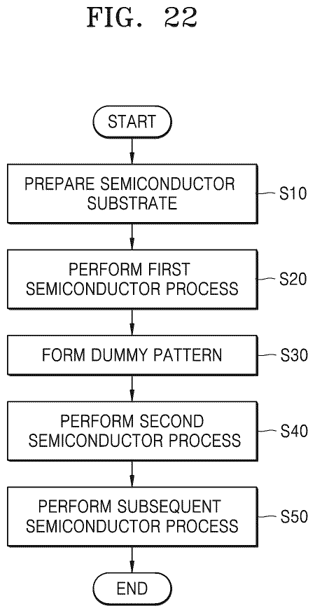

FIG. 22 illustrates a method of fabricating a semiconductor device, according to an embodiment. A description is given below with reference to FIGS. 1 to 21.

First, a semiconductor substrate 10 may be prepared (S10). The semiconductor substrate 10 may, for example, have already undergone various processes. For example, an oxidation process, a photolithography process, and/or an etching process may have been performed on the semiconductor substrate 10.

Subsequently, a first semiconductor process may be performed on the semiconductor substrate 10 (S20). The first semiconductor process may include an oxidation process, a photolithography process, and/or an etching process. The first semiconductor process is not limited to the above-described processes and may include other types of semiconductor processes.

While the first semiconductor process is performed, a first test pattern 110 may be formed on a semiconductor substrate 10. When the first semiconductor process is performed between layers at different vertical levels, the misalignment between these layers may be reduced by measuring the first test pattern 110.

Subsequently, a dummy pattern 120 may be formed above the semiconductor substrate 10 (S30). The dummy pattern 120 may be formed on the first test pattern 110. The dummy pattern 120 may overlap the first test pattern 110 in the vertical direction (the Z direction). The dummy pattern 120 may reduce the influence of the first test pattern 110 when subsequently measuring the second test pattern 130.

Operation S30 of forming the dummy pattern 120 on the semiconductor substrate 10 may be substantially the same as forming the dummy pattern 120 described in FIG. 20. That is, operation S30 may include receiving the process conditions for measuring the test pattern (S220), designing the dummy pattern 120 on the basis of the process conditions (S240), and evaluating the dummy pattern 120 (S260).

Subsequently, a second semiconductor process may be performed on the semiconductor substrate 10 (S40). The second semiconductor process may include an oxidation process, a photolithography process, and/or an etching process. The second semiconductor process is not limited to the above-described processes and may include other types of semiconductor processes. The second semiconductor process may be performed at a different vertical level layer than the first semiconductor process.

While the second semiconductor process is performed, a second test pattern 130 may be formed above the semiconductor substrate 10. When the second semiconductor process is performed between layers at different vertical levels, the misalignment between these layers may be reduced by measuring the second test pattern 130.

The second test pattern 130 may be formed above the first test pattern 110 and/or the dummy pattern 120. The second test pattern 130 may overlap the first test pattern 110 and/or the dummy pattern 120 in the vertical direction (the Z direction).

Then, subsequent semiconductor processes are performed (S50). The subsequent semiconductor processes on the semiconductor substrate 10 may include various processes. For example, the subsequent semiconductor processes may include a deposition process, an etching process, an ion process, a cleaning process, etc. In addition, the subsequent semiconductor process may include a singulation process for individualizing the semiconductor substrate 10 into individual semiconductor chips, a test process for testing the semiconductor chips, and a packaging process for packaging the semiconductor chips. The semiconductor device may be completed through the subsequent semiconductor processes on the semiconductor substrate 10.

A semiconductor device fabricating method according to the disclosure may provide the plurality of test patterns overlapping each other in the vertical direction (the Z direction). Accordingly, the test structures 100 may be effectively arranged in the semiconductor substrate 10, and thus, the space margin of the semiconductor substrate 10 may increase.

In addition, the semiconductor device fabricating method according to the disclosure includes forming the dummy pattern 120, and thus, the influence of the first test pattern 110 on the measurement may be reduced when measuring the second test pattern 130. Therefore, the semiconductor device fabricating method according to the disclosure may provide a method of manufacturing a semiconductor device having high reliability.

While the disclosure has been particularly shown and described with reference to embodiments of the disclosure, various changes in form and details may be made therein without departing from the spirit and scope of the following claims.

What is claimed is:

1. A semiconductor device comprising:
a semiconductor substrate; and
a test structure on the semiconductor substrate,
wherein the test structure comprises:
a first test pattern;
a second test pattern disposed above the first test pattern; and
a dummy pattern located between the first test pattern and the second test pattern, and
wherein the first test pattern, the dummy pattern, and the second test pattern at least partially overlap in a vertical direction.

2. The semiconductor device of claim 1, wherein at least one of the first test pattern or the second test pattern comprises a line-and-space pattern.

3. The semiconductor device of claim 1, wherein the dummy pattern comprises a line-and-space pattern.

4. The semiconductor device of claim 1, wherein at least one of the first test pattern, the dummy pattern, and the second test pattern comprises at least one of an image-based overlay (IBO) mark, a diffraction-based overlay (DBO) mark, a box-in-box (BIB) mark, and an advanced image metrology (AIM) mark.

5. The semiconductor device of claim 1, wherein at least one of the first test pattern, the dummy pattern, and the second test pattern comprises an alignment mark.

6. The semiconductor device of claim 1, wherein an extension direction of the dummy pattern is substantially same or the same as an extension direction of the first test pattern, and
wherein the extension direction of the dummy pattern is different from an extension direction of the second test pattern.

7. The semiconductor device of claim 1, wherein an extension direction of the dummy pattern is different from both an extension direction of the first test pattern and an extension direction of the second test pattern.

8. The semiconductor device of claim 1, wherein an extension direction of at least one of the first test pattern and the second test pattern is perpendicular or substantially perpendicular to an extension direction of the dummy pattern.

9. The semiconductor device of claim 1, wherein the dummy pattern is a first dummy pattern,
wherein the test structure further comprises:
a third test pattern disposed above the second test pattern; and
a second dummy pattern located between the second test pattern and the third test pattern, and
wherein the second test pattern, the second dummy pattern, and the third test pattern at least partially overlap in the vertical direction.

10. A method of fabricating a test structure, the method comprising:
forming a first test pattern on a semiconductor substrate;
forming a dummy pattern on the first test pattern; and
forming a second test pattern on the dummy pattern,
wherein the first test pattern, the dummy pattern, and the second test pattern at least partially overlap in a vertical direction.

11. The method of claim 10, wherein the forming of the dummy pattern comprises:
receiving a measurement process condition of a test pattern;
designing the dummy pattern; and
evaluating the dummy pattern.

12. The method of claim 11, wherein the measurement process condition comprises a wavelength of an overlay measuring device and a numerical aperture (NA) of the overlay measuring device.

13. The method of claim 11, wherein the designing of the dummy pattern comprises selecting a shape and an arrangement of the dummy pattern, based on information of the test pattern.

14. The method of claim 11, wherein the designing of the dummy pattern comprises calculating space efficiency of the test structure including the first test pattern, the dummy pattern, and the second test pattern.

15. The method of claim 10, wherein a planar shape of the dummy pattern comprises at least one of a polygon, a circle, and an ellipse.

16. A method of fabricating a semiconductor device, the method comprising:
preparing a semiconductor substrate;
performing a first semiconductor process on the semiconductor substrate;
forming a dummy pattern on the semiconductor substrate;
performing a second semiconductor process on the semiconductor substrate; and
performing a subsequent semiconductor process on the semiconductor substrate,
wherein the performing of the first semiconductor process comprises forming a first test pattern on the semiconductor substrate,
wherein the performing of the second semiconductor process comprises forming a second test pattern on the semiconductor substrate, and
wherein the first test pattern, the dummy pattern, and the second test pattern at least partially overlap in a vertical direction.

17. The method of claim 16, wherein the dummy pattern is designed based on information of a test pattern located at a higher vertical level than the dummy pattern.

18. The method of claim 16, wherein the first semiconductor process comprises performing overlay measurement based on the first test pattern, and
wherein the second semiconductor process comprises performing overlay measurement based on the second test pattern.

19. The method of claim 16, wherein all of the first test pattern, the dummy pattern, and the second test pattern extend in a same or substantially same direction.

20. The method of claim 16, wherein an extension direction of the second test pattern is different from at least one of an extension direction of the first test pattern and an extension direction of the dummy pattern.
